(19) United States
(12) Patent Application Publication
(10) Pub. No.: US 2017/0205840 A1
(43) Pub. Date: Jul. 20, 2017

(54) POWER-SUPPLY CIRCUIT

(71) Applicant: KABUSHIKI KAISHA TOSHIBA, Tokyo (JP)

(72) Inventor: Akio OGURA, Sinagawa Tokyo (JP)

(21) Appl. No.: 15/245,898

(22) Filed: Aug. 24, 2016

(30) Foreign Application Priority Data
Jan. 15, 2016 (JP) 2016-006110

(51) Int. Cl. G05F 1/46; H03K 5/24

(52) U.S. Cl. CPC G05F 1/46; H03K 5/24

(57) ABSTRACT

A power-supply circuit includes a first transistor connected to an output terminal, a second transistor configured to output a current corresponding to an output current of the first transistor, and an amplifier configured to regulate an output voltage at the output terminal at a predetermined level. A first constant current is caused to flow through the amplifier when the output current of the second transistor is smaller than the predetermined value, and a second constant current that is greater than the first constant current is caused to flow through the amplifier when the output current of the second transistor is greater than the predetermined value.

### CROSS-REFERENCE TO RELATED APPLICATION

This application is based upon and claims the benefit of priority from Japanese Patent Application No. 2016-006110, filed Jan. 15, 2016, the entire contents of which are incorporated herein by reference.

### FIELD

Embodiments described herein relate generally to a power-supply circuit.

### BACKGROUND

A linear regulator of one type in the related art switches an operational mode between a low-power consumption mode and a quick-response mode by sensing fluctuations in an output voltage caused by load variations and adjusting a current which flows through an amplifier of the regulator in accordance with the output voltage. However, in such a linear regulator, mode switching is performed based on a comparison between an output voltage and a threshold voltage. For that reason, depending on the settings of the threshold voltage, the mode switching may not be quickly and accurately performed. Today, more electronic devices are becoming driven by batteries and, at the same time, require a quick response to the load variation.

### DESCRIPTION OF THE DRAWINGS

FIG. 1 is a circuit diagram of a power-supply device according to a first embodiment.

FIG. 2 is a graph indicating a relationship between a load current and an additional current in the power-supply device according to the first embodiment in comparison to a comparative example.

FIG. 3 is a graph indicating a relationship between an output voltage and the load current of the power-supply device according to the first embodiment.

FIG. 4 is a circuit diagram of a power-supply device according to a specific example of the first embodiment.

FIG. 5 is a circuit diagram of a power-supply device according to a modified example of the first embodiment.

FIG. 6 is a circuit diagram of a power-supply device according to another modified example of the first embodiment.

FIG. 7 is a circuit diagram of a power-supply device according to a second embodiment.

FIG. 8 is a circuit diagram of a power-supply device according to a specific example of the second embodiment.

FIG. 9 is a circuit diagram of a power-supply device according to a modified example of the second embodiment.

FIG. 10 is a circuit diagram of a power-supply device according to another modified example of the second embodiment.

### DETAILED DESCRIPTION

One or more embodiments provide a power-supply device that can achieve both low power consumption and a quick response to connection of a load thereto.

In general, according to an embodiment, a power-supply device includes a first transistor connected to an output terminal, a second transistor configured to output a current corresponding to an output current of the first transistor, and an amplifier configured to regulate an output voltage at the output terminal at a predetermined level. A first constant current is caused to flow through the amplifier when the output current of the second transistor is smaller than the predetermined value, and a second constant current that is greater than the first constant current is caused to flow through the amplifier when the output current of the second transistor is greater than the predetermined value.

Hereinafter, embodiments will be described with reference to the drawings, but an embodiment is not limited to the following embodiments.

### First Embodiment

A power-supply device (circuit) according to a first embodiment compares a current output from a second transistor that monitors a current output from a first transistor, which functions as an output transistor, with a predetermined reference current, and increases a response speed of a first amplifier based on the comparison result. Hereinafter, a detailed description thereof will be given.

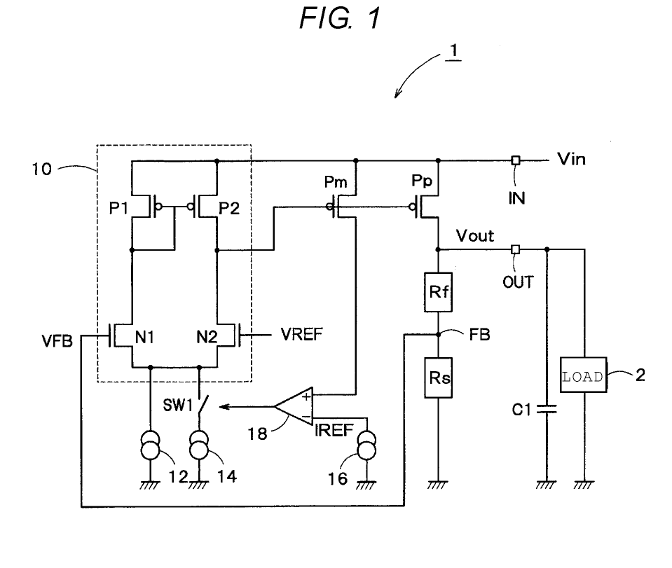

FIG. 1 is a circuit diagram of a power-supply device 1 according to the present embodiment. The power-supply device 1 according to the present embodiment includes a first amplifier 10, a first current source 12, a second current source 14, a first transistor Pp, a second transistor Pm, a reference current source 16, a current comparator 18, a first switch SW1, and resistors Rf and Rs.

The first amplifier 10 is a differential amplifier circuit that amplifies a difference of two voltages input thereto and includes, for example, transistors P1, P2, N1, and N2. The transistors P1 and P2 are pMOS transistors, and the transistors N1 and N2 are nMOS transistors. The gates of the transistors P1 and P2 are connected to each other, and the gate and the drain of the transistor P1 are connected to each other. Moreover, the sources of the transistors P1 and P2 are connected to an input terminal IN.

The drain of the transistor N1 is connected to the drain of the transistor P1, and a feedback voltage VFB corresponding to an output voltage Vout is applied to the gate of the transistor N1. The drain of the transistor N2 is connected to the drain of the transistor P2, and a reference voltage VREF which is a predetermined voltage is applied to the gate of the transistor N2. The sources of these transistors N1 and N2 are connected to the first current source 12. Moreover, the sources of the transistors N1 and N2 are connected to the second current source 14 via the first switch SW1.

Input nodes of the first amplifier 10 are the gates of the transistors N1 and N2. Moreover, an output node of the first amplifier 10 is a connection node between the drain of the transistor N2 and the drain of the transistor P2. To the input nodes of the first amplifier 10, the feedback voltage VFB and the reference voltage VREF are input, and a voltage corresponding to a difference of the feedback voltage VFB and the reference voltage VREF is output from the node between the drains of the transistors N2 and P2.

The first current source 12 is connected to both of the sources of the transistors N1 and N2 of the first amplifier 10. The first current source 12 supplies a current which flows through the first amplifier 10. The second current source 14 increases the current which flows through the first amplifier 10 when an output current of the second transistor Pm exceeds a predetermined threshold value. As described above, the second current source 14 is provided to increase the current which flows through the first amplifier 10 when a load current increases and the output current of the second transistor Pm accordingly exceeds the predetermined threshold value.

The first transistor Pp is an output transistor that outputs an output voltage Vout corresponding to an input voltage VREF. The source of the first transistor Pp is connected to the input terminal IN, the gate of the first transistor Pp is connected to the output node of the first amplifier 10, and the drain of the first transistor Pp is connected to an output terminal OUT. An output capacitor C1 and a load 2 are connected to the output terminal OUT.

The second transistor Pm is a transistor that monitors an output current of the first transistor Pp. That is, the second transistor Pm outputs a current corresponding to the output current of the first transistor Pp. The source of the second transistor Pm is connected to the input terminal IN, and the gate of the second transistor Pm is connected to the output node of the first amplifier 10. Since the gates of the first transistor Pp and the second transistor Pm are directly connected to each other and the sources of the first transistor Pp and the second transistor Pm are also directly connected to each other, the first transistor Pp and the second transistor Pm substantially forma current mirror circuit. As a result, a current proportional to the output current of the first transistor Pp flows from the second transistor Pm.

The reference current source 16 causes a reference current IREF, which is a predetermined current serving as a threshold value, to flow to the current comparator 18. The current comparator 18 outputs a signal which performs switching of ON/OFF of the first switch SW1 connected to the second current source 14 based on the result of comparison between a drain current of the second transistor Pm and the reference current IREF.

The resistors Rf and Rs are connected in series between the drain of the first transistor Pp and a ground node. The resistors Rf and Rs are used to obtain the feedback voltage VFB by dividing the output voltage Vout. The voltage VFB is applied to the gate of the transistor N1.

Next, the operation of the power-supply device 1 will be described.

First, a case where the input voltage Vin is applied to the input terminal IN and the load 2 is not connected to the output terminal OUT will be described. When the input voltage Vin is not applied, all transistors including the first transistor Pp are turned off, and both the output voltage Vout and the feedback voltage VFB are ground level. When the input voltage Vin is applied, the first amplifier 10 starts to perform feedback control. Since the reference voltage VREF, which is greater than ground level, is applied to the gate of the transistor N2, the transistor N2 allows more current to flow therethrough, compared to the transistor N1. That is, the current from the current source 12 through the drain of the transistor N2 is greater than the current from the current source 12 through the drain of the transistor N1. A drain current of the transistor P1 is equal to a drain current of the transistor N1. A drain current of the transistor P2 is potentially same as a drain current of the transistor N2. However, the drain current of the transistor P2 is practically limited to the drain current of the transistor P1, since gate and source voltages of the transistor P1 and the transistor P2 are respectively identical. The transistor N2 allows more current to flow therethrough than the current that the transistor P2 can provide, so that the drain voltage of the transistor N2, which is the gate voltage of the transistor Pp, goes down. Therefore, a voltage between the source and the gate of the transistor Pp increases, and the transistor Pp is turned on. When the first transistor Pp is turned on, a voltage Vout is output from the output terminal OUT. Therefore, a current of Vout/(Rf+Rs) flows through the resistors Rf and Rs. The feedback voltage VFB equals to Vout·Rs/(Rf+Rs). The first amplifier 10 performs feedback control so that the feedback voltage VFB becomes equal to the reference voltage VREF.

When the load 2 is not connected to the output terminal OUT of the power-supply device 1, feedback control is performed as described above such that the output voltage Vout becomes a fixed voltage (VREF)×(1+Rf/Rs). As the load 2 is not connected, both the current of the transistor Pp and the current of the transistor Pm are minimal. As the current of the transistor Pm is less than IREF 16, the comparator 18 outputs a low-level signal and SW1 is in an off state. In such a state, the current which flows through the first amplifier 10 is supplied from the first current source 12. Therefore, the current from the second current source 14 is not supplied to the first amplifier 10.

Next, a case where the load 2 is connected to the output terminal OUT of the power-supply device 1 will be described. The power-supply device 1 according to the present embodiment includes the second transistor Pm that forms the current mirror circuit with the first transistor Pp, and the second transistor Pm causes an output current corresponding to the output current of the first transistor Pp to flow therethrough. When the load 2 is connected to the output terminal OUT of the power-supply device 1 and the output voltage Vout decreases in accordance with an increase in the load current, the output current of the second transistor Pm increases. When the output current of the second transistor Pm exceeds the reference current IREF, the output of the current comparator 18 is inverted. As a result, the first switch SW1 is brought into conduction and, in addition to the current of the first current source 12, the current regulated by the second current source 14 flows through the first amplifier 10. Thereby, the responsiveness of the first amplifier 10 is improved.

That is, an output current of the transistor N2 increases as compared to a case where the second current source 14 is not provided, and as a result a gate voltage of the first transistor Pp decreases more quickly. Further, the first transistor Pp increases a drain current more promptly and returns the output voltage Vout to a stable voltage quickly. In the present embodiment, a state in which only the current regulated by the first current source 12 flows through the first amplifier 10 is referred to as a low-power-consumption mode and a state in which the currents regulated by the first current source 12 and the second current source 14 flow through the first amplifier 10 is referred to as a quick-response mode.

As described above, in the present embodiment, when the power-supply device 1 is connected to the load 2, the mode is caused to transition from the low-power-consumption mode to the quick-response mode promptly, and the current regulated by the second current source 14 flow through the first amplifier 10, whereby fluctuations in the output voltage Vout are suppressed more quickly. This quick-response mode continues while the load 2 is connected to the power-supply device 1.

Moreover, when the load 2 is disconnected from the power-supply device 1, the drain current of the second transistor Pm becomes smaller than the reference current IREF and the first switch SW1 is turned off by an output signal from the current comparator 18. As a result, the current regulated by the second current source 14 stops flowing through the first amplifier 10, and the mode transitions to the low-power-consumption mode. As described above, by monitoring the output current of the first transistor Pp, the switching from the quick-response mode to the low-power-consumption mode can be performed promptly. The present embodiment can also add some delay time when the mode switches from the quick-response mode to the low-power-consumption mode to give the first amplifier 10 enough time to cause the output voltage Vout back to stable voltage during the quick-response mode. The power-supply device 1 would be switched to low-power-consumption mode after the delay time.

Here, if the second transistor Pm in FIG. 1 were not provided, as increase of the load current flowing to the load 2 from the power-supply device 1, the output voltage Vout would decrease. As a result, the current flowing to the resistors Rf and Rs would decrease, and the feedback voltage VFB would also become lower than the reference voltage VREF. In this case, since the voltage which is applied to the gate of the transistor N1 decreases, an output current (a drain-source current) of the transistor N1 decreases. Therefore, an output current of the transistor P1 also decreases, but output currents of the transistors P2 and N2 increase.

Then, the gate voltage of the first transistor Pp decreases and the output current of the first transistor Pp increases, and an operation to increase the output voltage Vout is performed. Since such a feedback operation takes time, quick responsiveness would be impaired. In contrast, in the present embodiment, as described above, by providing the second transistor Pm, the current flowing through the first amplifier 10 is increased when the load current increases rapidly and quick responsiveness is improved.

As described above, according to the present embodiment, when the load 2 is connected to the power-supply device 1, by monitoring the output current of the first transistor Pp and adding the current of the second current source 14 to the first amplifier 10, the responsiveness of the first amplifier 10 is enhanced. That is, switching from the low-power-consumption mode to the quick-response mode is performed promptly. Moreover, as long as the load 2 is connected to the power-supply device 1, the quick-response mode is maintained, and as a result fluctuations in the output voltage Vout can be suppressed promptly in accordance with the output current of the first transistor Pp.

If an output voltage of the first transistor Pp, instead of the output current of the first transistor Pp, is monitored, fluctuations in the output voltage cannot be easily sensed accurately. If a threshold voltage to transition to the quick-response mode is too close to the stable output voltage Vout, e.g. (Vout−30 mV), an acceptable voltage error would be less than 1%, which is not easily sensed by the MOS transistor circuit. Appropriate filtering time may be needed to obtain stable comparator results, which causes Vout fluctuation sensing time longer. If a threshold voltage to transition to the quick-response mode is too far from the stable output voltage Vout, e.g. (Vout−0.2V), fluctuation of the output voltage Vout caused by the load 2 may become worse than the present embodiment, because the fluctuations in the present embodiment is less than (Vout−0.1V) as depicted in FIG. 3. As in the present embodiment, by sensing the output current as it is, instead of the output voltage Vout, load variations can be sensed more promptly and accurately. For example, 10% variation of the threshold current value does not cause significant change on the fluctuation of the output voltage Vout caused by the change of the load 2, because the power-supply device 1 is always at quick-response mode unless the load 2 is not connected. As a result, the mode can transition to the quick-response mode promptly when the load is connected, and the mode can transition to the low-power-consumption mode promptly when the load 2 is disconnected from the power-supply device 1. Moreover, if the current which flows through the transistor is assumed to be I, since noise is generated in proportion to 1/√I, by making a large current flow through the first amplifier 10 using the second current source 14, a reduction of noise in the first amplifier 10 can also be achieved.

As a first comparative example of the present embodiment, an additional current corresponding to the output current of the second transistor Pm may be caused to flow through the first amplifier 10. In this case, in the first amplifier 10, the larger the output current of the first transistor Pp is, that is, the larger the load current is, the larger the additional current which flows through the first amplifier 10 becomes. On the other hand, in the present embodiment, irrespective of the magnitude of the load current, a constant additional current is caused to flow through the first amplifier 10 by the second current source 14.

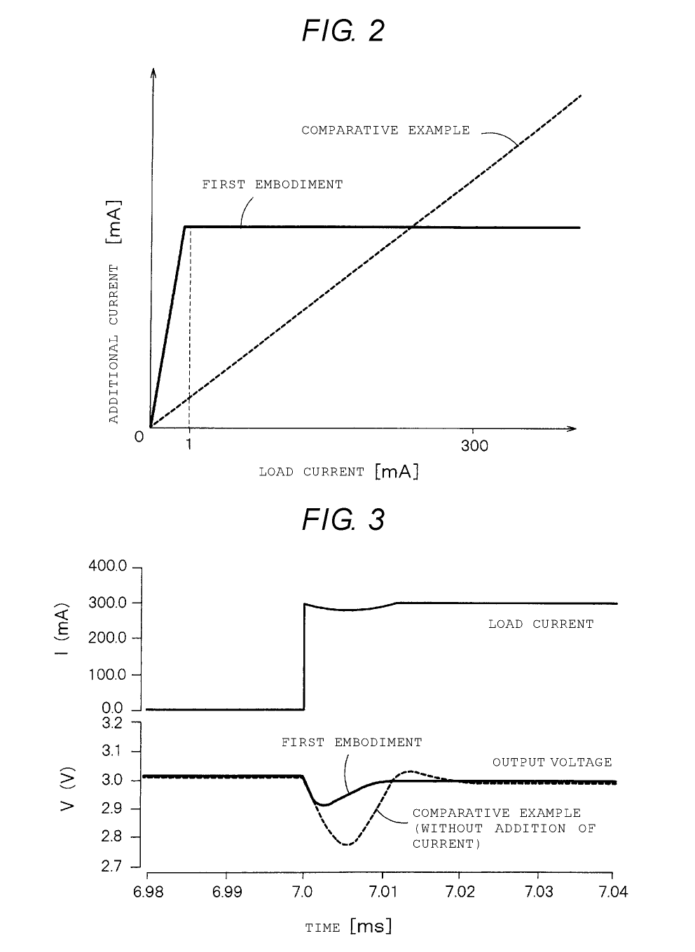

FIG. 2 is a graph indicating the additional currents flowing through the first amplifier 10 in the present embodiment and the first comparative example. The horizontal axis in FIG. 2 represents the load current [mA] and the vertical axis represents the additional current [mA], and the solid line indicates the present embodiment and the dashed line indicates the first comparative example. As depicted in FIG. 2, in the first comparative example, the current which flows through the first amplifier 10 changes in proportion to the load current of the power-supply device 1. Therefore, in the first comparative example, since the current which flows through the first amplifier 10 does not increase to a desired level until the load current increases to a certain level, responsiveness to load variations is not good. In contrast, with the additional current according to the present embodiment, since a nearly constant additional current flows through the first amplifier 10 when the load 2 is connected, the first amplifier 10 can perform a quicker response. Furthermore, power consumption of the first comparative example is higher than the one according to the first embodiment and occasionally exceeds a range to keep the feedback system stable, since the current flowing through the first amplifier 10 increases as the load current increases.

FIG. 3 is a graph indicating changes in the output voltage in accordance with load variations in the present embodiment and a second comparative example of the power-supply device having no second current source 14. The horizontal axis represents time [ms] and the vertical axis represents the voltage [V], and the solid line indicates the present embodiment and the dashed line indicates the second comparative example. Moreover, FIG. 3 also depicts changes in a load current in accordance with load variations. As depicted in FIG. 3, in the second comparative example, when the load current increases to 300 mA from 1 mA, for example, the output voltage of the power-supply device 1 decreases by about 0.2 V. On the other hand, in the present embodiment, even when the load current increases, a voltage decrease is controlled to be about 0.1 V. Furthermore, as compared to the second comparative example, the power-supply device 1 according to the present embodiment can suppress fluctuations in the output voltage quickly in response to an increase in the load and can return to a stable voltage more rapidly.

### Specific Example of the First Embodiment

The second current source 14, the reference current source 16, the current comparator 18, and the first switch SW1 in the first embodiment can be configured using transistors and resistors.

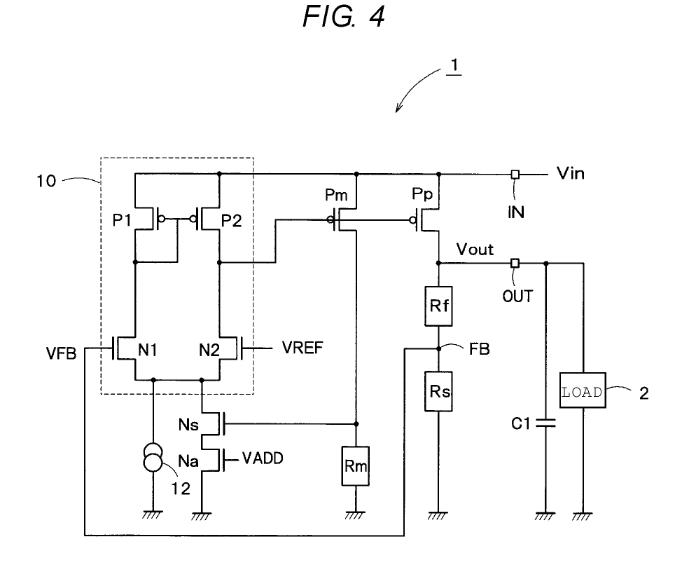

FIG. 4 depicts a specific example of the power-supply device 1 which does not use the second current source 14, the reference current source 16, and the current comparator 18. In the power-supply device 1 depicted in FIG. 4, the second current source 14 is configured using a transistor Na, and the reference current source 16, the current comparator 18, and the first switch SW1 are configured using a resistor Rm and a transistor Ns.

The resistor Rm is connected between the drain of the second transistor Pm and the ground node. With the resistor Rm, a voltage corresponding to the output current of the second transistor Pm is output. This voltage is input to the gate of the transistor Ns.

The drain of the transistor Ns is connected to the first amplifier 10 and the source of the transistor Ns is connected to the drain of the transistor Na. The transistor Ns performs switching operation of the first switch SW1 and is turned on when the load current increases and the output current of the second transistor Pm increases.

The transistor Na is an nMOS transistor, for example. A predetermined voltage VADD is applied to the gate of the transistor Na, the drain of the transistor Na is connected to the source of the transistor Ns, and the source of the transistor Na is grounded. The transistor Na causes a drain current of the transistor Na to flow through the first amplifier 10 via the drain-source of the transistor Ns when the transistor Ns is on.

### Modified Example of the First Embodiment

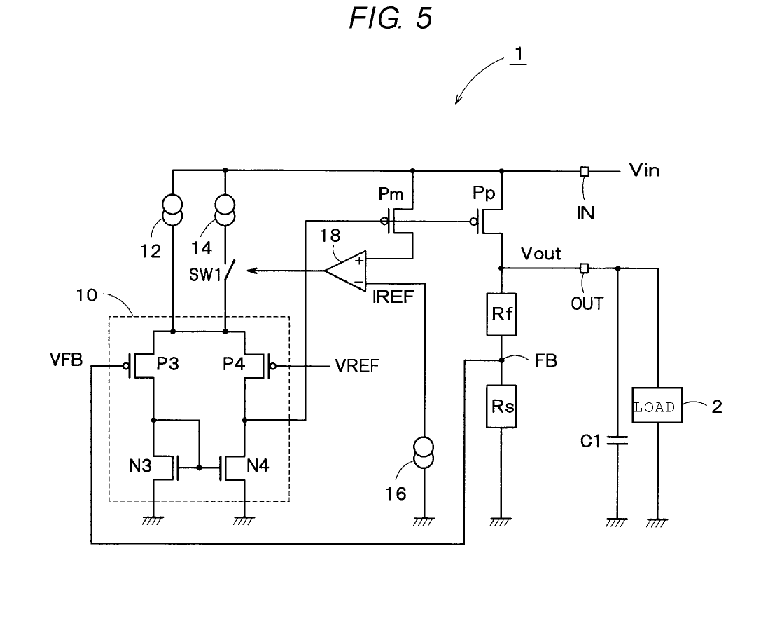

FIG. 5 is a circuit diagram of a power-supply device according to a modified example of the first embodiment. The power-supply device according to the modified example depicted in FIG. 5 is obtained by reversing the conductivity types of the transistors depicted in FIG. 1 except for the first transistor Pp and the second transistor Pm. In FIG. 5, the first current source 12 and the second current source 14 are connected to the input voltage Vin node, and the first amplifier 10 is connected to the ground node. Moreover, transistors P3 and P4 in the first amplifier 10, to which the feedback voltage VFB and the reference voltage VREF are input, respectively, are pMOS transistors, and transistors N3 and N4 connected to the transistors P3 and P4 are nMOS transistors. Since the circuit operation in FIG. 5 is the same as the circuit operation in FIG. 1, a detailed description thereof is omitted.

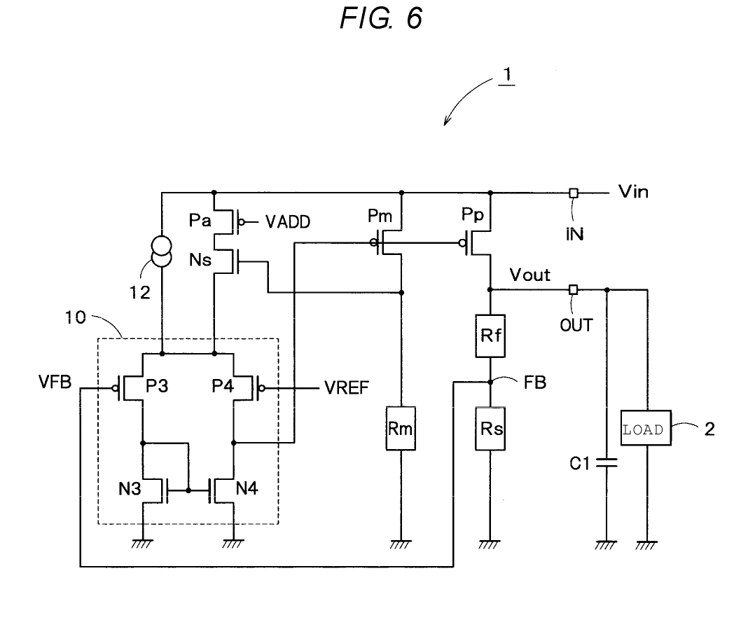

FIG. 6 depicts a power-supply device in which the second current source 14, the reference current source 16, the current comparator 18, and the first switch SW1 in FIG. 5 are configured using transistors Pa and Ns and the resistor Rm as in the example shown in FIG. 4. Since the circuit configuration and the circuit operation in FIG. 6 are the same as the circuit configuration and the circuit operation in FIG. 4, a detailed description thereof is omitted.

As described above, in the modified example of the first embodiment, when the output current of the second transistor Pm monitoring the output current of the first transistor Pp increases, the current which flows through the first amplifier 10 increases. Therefore, when the load increases and the output current of the first transistor Pp increases, the responsiveness of the first amplifier 10 can be improved and fluctuations in the output voltage Vout of the power-supply device 1 can be suppressed promptly. As a result, when the load 2 is not connected, the power-supply device 1 of the present embodiment operates in the low-power-consumption mode, and when the load 2 is connected, the power-supply device 1 can promptly switch to the quick-response mode.

The power-supply devices 1 according to the first embodiment (FIG. 1) and the specific example and the modified examples (FIGS. 4 to 6) of the first embodiment produce similar advantage and effects as described above, and the embodiment thereof may be changed, if necessary, by various factors such as the circuit layout relationship.

### Second Embodiment

A power-supply device according to a second embodiment is also directed to achieving low noise by using a second amplifier which controls gain in addition to the first amplifier 10. Hereinafter, a difference from the first embodiment will be described in detail.

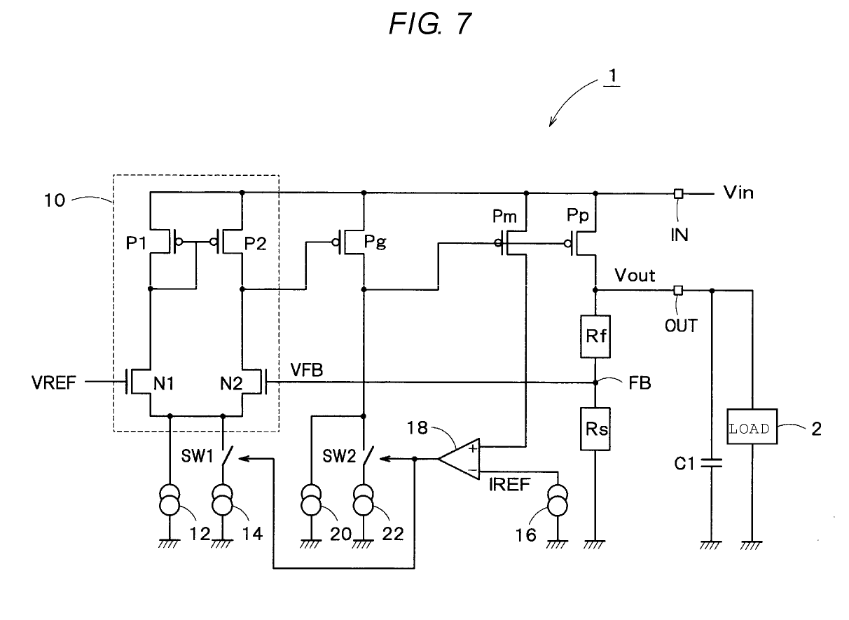

FIG. 7 depicts a power-supply device 1 according to the present embodiment. In addition to the circuit elements in FIG. 1, the power-supply device 1 depicted in FIG. 7 further includes a transistor Pg which is a second amplifier, a third current source 20, a fourth current source 22, and a second switch SW2.

The transistor Pg, which is the second amplifier, is a pMOS transistor, for example. The source of the transistor Pg is connected to the input terminal, the gate of the transistor Pg is connected to the output of the first amplifier 10, and the drain of the transistor Pg is connected to the gate of the first transistor Pp, the gate of the second transistor Pm, and the third current source 20 and the fourth current source 22. The transistor Pg performs gate drive of the first transistor Pp.

In such a configuration, a potential obtained by reversing the gate potential of the transistor Pg is input to the gates of the first transistor Pp and the second transistor Pm. As a result, each of the voltages applied to the gates of the transistors N1 and N2 of the first amplifier 10 becomes the reverse of the voltage in the above-described embodiment. That is, the reference voltage VREF is applied to the gate of the transistor N1 and the feedback voltage VFB is applied to the gate of the transistor N2.

In the power-supply device 1 in FIG. 7, the gain of the output voltage of the first amplifier 10 is controlled by the transistor Pg. A drain voltage of the transistor Pg is supplied to the gates of the first transistor Pp and the second transistor Pm. For example, when the load current increases and the output voltage Vout decreases, the output current of the second transistor Pm increases in accordance with an increase in the output current of the first transistor Pp. When the output current of the second transistor Pm exceeds the reference current IREF, the output of the current comparator 18 is inverted and the first switch SW1 and the second switch SW2 are brought into conduction. As a result, in addition to the current of the first current source 12, the current regulated by the second current source 14 flows through the first amplifier 10, and as a result the responsiveness of the first amplifier 10 is improved. At the same time, in addition to a current of the third current source 20, a current regulated by the fourth current source 22 flows through the drain of the transistor Pg and to the gates of the first transistor Pp and the second transistor Pm. As a result, the responsiveness of the first transistor Pp and the second transistor Pm is improved.

Moreover, as a result of the transistor Pg being provided, the open gain (which is assumed to be A) of the first amplifier 10 increases. If a predetermined feedback factor determined by the value of the output voltage Vout is assumed to be β, the magnitude of noise or ripples depending on the input voltage Vin which is applied to the input terminal IN varies in accordance with the value of 1/(1+Aβ). Therefore, by increasing the open gain A, noise in the output voltage Vout can be reduced and ripples in the output voltage Vout can be eliminated efficiently. The consumed current of the power-supply device 1 according to the second embodiment slightly increases as compared to the consumed current of the power-supply device 1 according to the first embodiment, but, as in the case of the first embodiment, both a low-power-consumption and a quick response can be achieved. Furthermore, as compared to the first embodiment, noise in the output voltage Vout can be further reduced and ripples in the output voltage Vout can be eliminated more efficiently.

### Specific Example and Modified Example of the Second Embodiment

Also in the second embodiment, a specific example and a modified example similar to the specific example and the modified examples of the first embodiment are applicable.

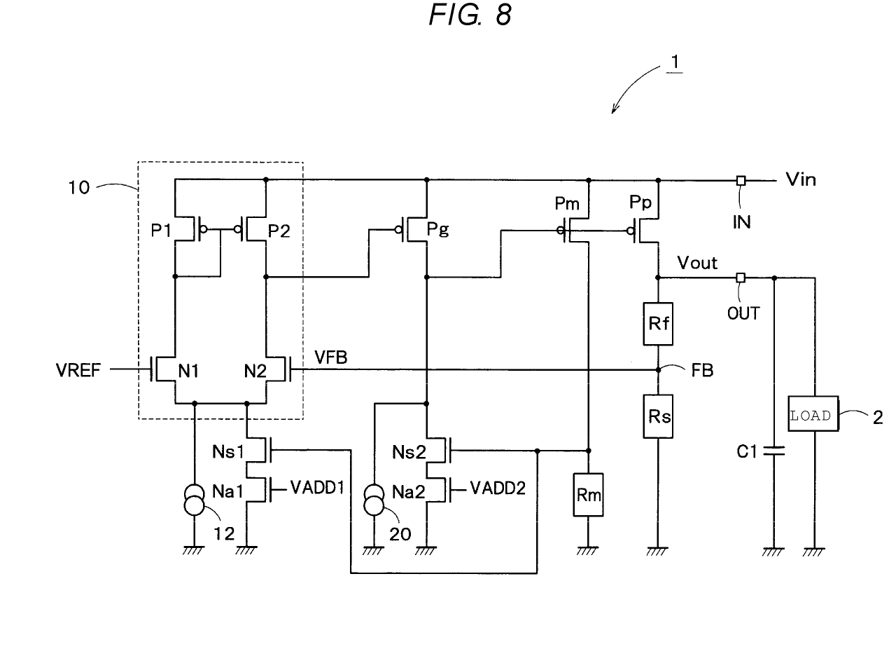

FIG. 8 depicts an example of a power-supply device in which the second current source 14, the reference current source 16, the current comparator 18, the first switch SW1, the second switch SW2, and the fourth current source 22 in FIG. 7 are configured using transistors and resistors as in the example shown in FIG. 4. The second current source 14 is configured using an nMOS transistor Na1. The current comparator 18 and the first switch SW1 are configured using an nMOS transistors Ns1. The fourth current source 22 is configured using an nMOS transistor Na2. The current comparator 18 and the second switch SW2 are configured using an nMOS transistor Ns2.

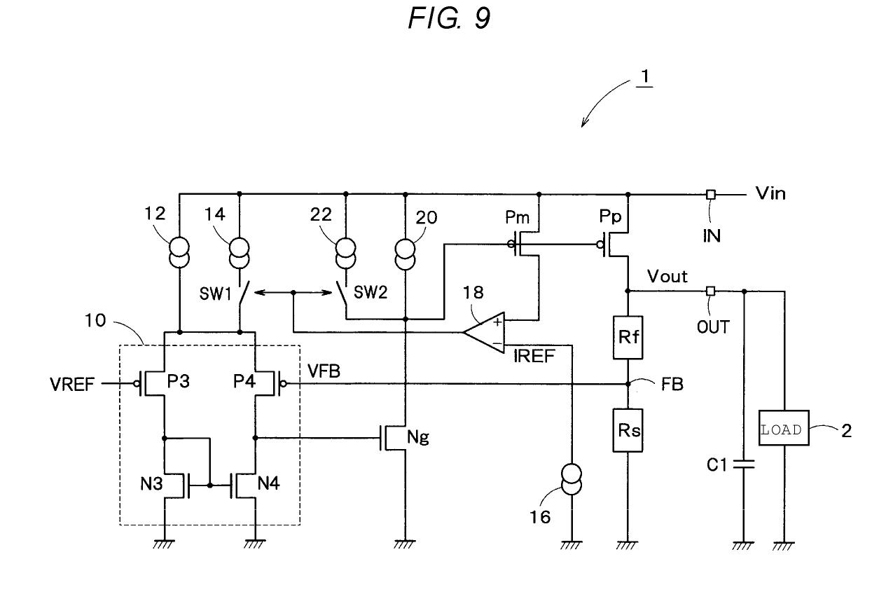

FIG. 9 illustrates a power-supply device obtained by reversing the conductivity types of the transistors depicted in FIG. 7 except for the first transistor Pp and the second transistor Pm. The first current source 12, the second current source 14, the third current source 20, and the fourth current source 22 are connected to the input voltage Vin node, and the first amplifier 10 is connected to the ground node. Moreover, the transistors P3 and P4 in the first amplifier 10, to which the reference voltage VREF and the feedback voltage VFB are input, are pMOS transistors, and the transistors N3 and N4 connected to the transistors P3 and P4 are nMOS transistors. Since the circuit operation in FIG. 9 is the same as the circuit operation in FIG. 7, a detailed description thereof is omitted.

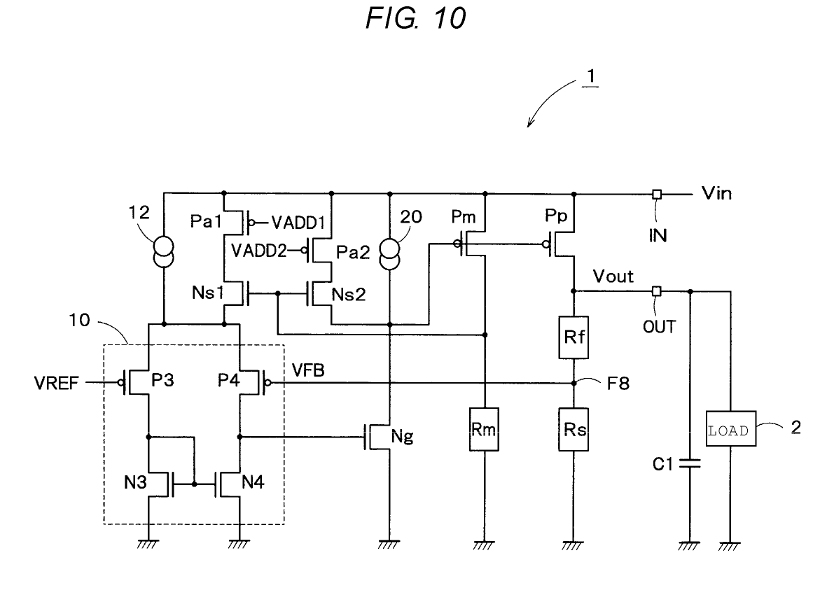

FIG. 10 depicts an example of a power-supply device in which the second current source 14, the reference current source 16, the current comparator 18, the first switch SW1, the second switch SW2, and the fourth current source 22 in FIG. 9 are configured using transistors and resistors as in the case in FIG. 8. The second current source 14 is configured using a pMOS transistor Pa1. The current comparator 18 and the first switch SW1 are configured using the nMOS transistor Ns1. The fourth current source 22 is configured using a pMOS transistor Pa2. The current comparator 18 and the second switch SW2 are configured using the nMOS transistor Ns2.

The power-supply devices 1 according to the second embodiment (FIG. 7) and the specific example and the modified examples (FIGS. 8 to 10) of the second embodiment produce similar advantage and effects as described above, and the embodiment thereof may be changed, if necessary, by various factors such as the circuit layout relationship.

While certain embodiments have been described, these embodiments have been presented by way of example only, and are not intended to limit the scope of the inventions. Indeed, the novel embodiments described herein may be specified in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

For example, in all the embodiments described above, some of the component elements and the load 2 are grounded, but these component elements and the load 2 may be connected to a predetermined voltage Vss as long as the resistor Rs and a voltage serving as a reference voltage for the load 2 become the same voltage.

What is claimed is:

1. A power supply circuit, comprising:
a first transistor connected to an output terminal;
a second transistor configured to output a current corresponding to an output current of the first transistor; and
an amplifier configured to regulate an output voltage at the output terminal at a predetermined level, wherein
a first constant current is caused to flow through the amplifier when the output current of the second transistor is smaller than the predetermined value, and
a second constant current that is greater than the first constant current is caused to flow through the amplifier when the output current of the second transistor is greater than the predetermined value.

2. The power supply circuit according to claim 1, wherein
the second transistor outputs a current proportional to the output current of the first transistor.

3. The power supply circuit according to claim 1, further comprising:
a first constant current source connected to the amplifier; and
a second constant current source connected to the amplifier through a switch, in parallel to the first constant current source, wherein
the switch is turned on when the output current of the second transistor exceeds the predetermined value.

4. The power supply circuit according to claim 3, further comprising:
a current comparator connected to the second transistor and a third constant current source of the predetermined value, and configured to turn on the switch when the output current of the second transistor exceeds the predetermined value.

5. The power supply circuit according to claim 1, wherein
the output current of the first transistor reduces fluctuation of the output voltage more quickly when the second constant current flows through the amplifier than when the first constant current flows through the amplifier.

6. The power supply circuit according to claim 1, wherein
the output current of the first transistor reduces an amount of fluctuation of the output voltage more when the second constant current flows through the amplifier than when the first constant current flows through the amplifier.

7. The power supply circuit according to claim 1, wherein
the amplifier includes third and fourth transistors connected in series, and fifth and sixth transistors connected in series and in parallel to a serial connection of the third and fourth transistors,
gates of the third and fifth transistors are connected to each other, a drain of the third transistor is connected to the gate of the third transistor, a drain of the fifth transistor is connected to gates of the first and second transistors, a gate of the fourth transistor is connected to a drain of the first transistor, and a gate of the sixth transistor is connected to a reference voltage source.

8. The power supply circuit according to claim 1, further comprising:
a second amplifier configured to control a gain of an output of the first amplifier, wherein
a third constant current is caused to flow through the second amplifier when the output current of the second transistor is smaller than the predetermined value, and
a fourth constant current that is greater than the third constant current is caused to flow through the second amplifier when the output current of the second transistor is greater than the predetermined value.

9. The power supply circuit according to claim 8, further comprising:
a third constant current source connected to the second amplifier; and
a fourth constant current source connected to the second amplifier through a second switch, in parallel to the third constant current source, wherein
the second switch is turned on when the output current of the second transistor exceeds the predetermined value.

10. The power supply circuit according to claim 8, wherein
the second amplifier includes a transistor having a gate connected to an output node of the amplifier and a drain connected to gates of the first and second transistors.

11. A power supply circuit, comprising:
a first transistor connected to an output terminal;
a second transistor configured to output a current corresponding to an output current of the first transistor;
an amplifier configured to regulate an output voltage of at the output terminal at a predetermined level;
a first constant current source connected to the amplifier; and
a second constant current source connected to the amplifier in parallel to the first constant current source, wherein
a connection between the second constant current source and the amplifier is established, when the output current of the second transistor exceeds a predetermined value.

12. The power supply circuit according to claim 11, wherein
the second transistor outputs a current proportional to the output current of the first transistor.

13. The power supply circuit according to claim 11, further comprising:
a switch connected between the second constant current source and the amplifier, the switch being turned on, when the output current of the second transistor exceeds the predetermined value.

14. The power supply circuit according to claim 11, further comprising:
a current comparator connected to the second transistor and a third constant current source of the predetermined value, and configured to turn on the switch, when the output current of the second transistor exceeds the predetermined value.

15. The power supply circuit according to claim 11, wherein
when the connection between the second constant current source and the amplifier is established, fluctuation of the output voltage of the first transistor decreases more quickly than when the connection is not established.

16. The power supply circuit according to claim 11, wherein
an amount of fluctuation of the output voltage of the first transistor is decreased when the connection between the second constant current source and the amplifier is established than when the connection is not established.

17. The power supply circuit according to claim 11, further comprising:
a second amplifier configured to control a gain of an output of the first amplifier;
a third constant current source connected to the second amplifier; and
a fourth constant current source connected to the second amplifier, in parallel to the third constant current source, wherein
a connection between the fourth constant current source and the second amplifier is established, when the output current of the second transistor exceeds the predetermined value.

18. The power supply circuit according to claim 17, further comprising:
a second switch connected between the fourth constant current source and the second amplifier, the second switch being turned on, when the output current of the second transistor exceeds the predetermined value.

19. A power supply circuit, comprising:
a first transistor connected to an output terminal;
a second transistor configured to output a current corresponding to an output current of the first transistor; and
an amplifier configured to regulate an output voltage at the output terminal at a predetermined level, wherein a current flowing through the amplifier is varied between a first current level and a second current level based on an output current of the first transistor.

20. The power supply circuit according to claim 19, further comprising:
a current comparator having a first input connected to the output of the second transistor and a second input connected to a reference current; and
a switch that is controlled to switch the current flowing through the amplifier to be at the first or second current level in accordance with an output of the current comparator.
